(19) United States
(12) Patent Application Publication
(10) Pub. No.: US 2026/0040617 A1
(43) Pub. Date: Feb. 5, 2026

(54) THIN FILM TRANSISTOR, METHOD FOR MANUFACTURIING THE THIN FILM TRANSISTOR AND DISPLAY APPARATUS COMPRISING THE SAME

(71) Applicant: LG Display Co., Ltd., Seoul (KR)

(72) Inventors: Jaeyoon PARK, Paju-si (KR); Dongyeon KANG, Paju-si (KR); Hyeonjoo SEUL, Paju-si (KR); Sungju CHOI, Paju-si (KR)

(73) Assignee: LG Display Co., Ltd., Seoul (KR)

(21) Appl. No.: 19/199,151

(22) Filed: May 5, 2025

(30) Foreign Application Priority Data
Aug. 5, 2024 (KR) 10-2024-0103956

(51) Int. Cl. H10D 30/67; H10D 30/01; H10D 86/01; H10D 86/40; H10D 86/60; H10K 59/121

(52) U.S. Cl. CPC H10D 30/6704; H10D 30/0314; H10D 30/6706; H10D 30/6731; H10D 86/0251; H10D 86/451; H10D 86/60; H10K 59/1213

(57) ABSTRACT

One embodiment of the present disclosure seeks to provide a thin film transistor and display device comprising: an active layer; a cover insulating film on the active layer; a first cover layer on the cover insulating film; and a gate electrode spaced apart from the active layer and at least partially overlapping the active layer, wherein the first cover layer covers an top surface of the cover insulating film and a side surface of the active layer, and the first cover layer includes an oxide semiconductor material and has a resistivity greater than that of the active layer.

### CROSS-REFERENCE TO RELATED APPLICATIONS

This application claims the benefit of priority of the Korean Patent Application No. 10-2024-0103956 filed on Aug. 5, 2024, which is hereby incorporated by reference as if fully set forth herein.

### BACKGROUND

### Technical Field

The present disclosure relates to a thin film transistor, method for manufacturing the thin film transistor and display apparatus comprising the same.

### Description of the Related Art

Transistors are widely used as switching devices or driving devices in the field of electronic devices. In particular, since a thin film transistor may be manufactured on a glass substrate or a plastic substrate, it is widely used as a switching device of a display apparatus such as a liquid crystal display apparatus or an organic light emitting device.

Based on the material constituting the active layer, thin film transistors can be divided into amorphous silicon thin film transistors using amorphous silicon as the active layer, polycrystalline silicon thin film transistors using polycrystalline silicon as the active layer, and oxide semiconductor thin film transistors using oxide semiconductors as the active layer.

In an oxide semiconductor thin film transistor (TFT), since the oxide constituting the active layer can be formed at a relatively low temperature, has high mobility, and has a large resistance change according to the oxygen content, desired physical properties can be easily obtained. Also, due to the nature of the oxide, since the oxide semiconductor is transparent, it is also advantageous to implement a transparent display.

### BRIEF SUMMARY

While oxide semiconductor thin film transistors in the related art offer several advantages, oxide semiconductors can increase defects in the active layer due to chemical damage caused by etchants when patterning the active layer. Specifically, defects can increase in the width direction of the active layer. In addition, the penetration depth of conductorization penetration increases due to the influence of hydrogen on the active layer, and as a result, the length of the effective channel decreases, which can deteriorate the operating stability of the device.

Accordingly, the inventors of the present disclosure have developed various embodiments of thin film transistors designed to suppress the increase of defects along the width direction of the active layer and to mitigate the adverse effects of hydrogen. Namely, the present disclosure has been made in view of the various technical problems in the related art, including the above problems and the various embodiments of the present disclosure provide a thin film transistor in which a cover insulating film and a first cover layer including an oxide semiconductor material are disposed, thereby preventing an increase in defects in an active layer due to chemical damage of an etchant.

A thin film transistor (TFT) structure according to certain embodiments of the present disclosure includes protective insulating films and cover layers positioned above and below the active layer, particularly along its side surfaces. These layers are composed of oxide semiconductor materials characterized by high resistivity and elevated oxygen content, and they serve to enhance both the protection and performance of the TFT. The various TFT structures disclosed herein are designed to prevent defects in the active layer during etching (e.g., blocks chemical damage from etching, for example, at the sidewalls), reduce or minimize hydrogen-induced degradation (e.g., reduces hydrogen diffusion effects), and improve overall stability and reliability of the TFT. The foregoing technical advantages are exemplary and not exhaustive; additional benefits may be apparent from the detailed embodiments described herein.

For instance, one embodiment of the present disclosure is to provide a thin film transistor in which a cover insulating film and a first cover layer including an oxide semiconductor material are disposed, thereby reducing the influence of hydrogen.

Another embodiment of the present disclosure is to provide a display device including such a thin film transistor.

In accordance with an aspect of the present disclosure, the above and other objects can be accomplished by the provision of a thin film transistor including an active layer; a cover insulating film on the active layer; a first cover layer on the cover insulating film; and a gate electrode spaced apart from the active layer and at least partially overlapping the active layer; wherein the first cover layer covers an top surface of the cover insulating film and a side surface of the active layer, and the first cover layer includes an oxide semiconductor material and has a resistivity greater than that of the active layer.

When the longitudinal direction of the active layer is referred to as a first direction and a direction perpendicular to the first direction is referred to as a second direction, the first cover layer can cover the side surface of the active layer based on the first direction and the second direction.

The first cover layer can be in contact with the top surface of the cover insulating film and the side surface of the active layer.

The cover insulating film is patterned, and the first cover layer can be in contact with the side surface of the cover insulating film.

The entire area of the cover insulating film can be disposed on the active layer.

The first cover layer includes an oxide semiconductor material, and the first cover layer includes at least one of an IGZO (InGaZnO)-based oxide semiconductor material, an IGO (InGaO)-based oxide semiconductor material, an IGZTO (InGaZnSnO)-based oxide semiconductor material, a GZTO (GaZnSnO)-based oxide semiconductor material, a GZO (GaZnO)-based oxide semiconductor material, and a GO (GaO)-based oxide semiconductor material, and the first cover layer may have a higher concentration of oxygen atom than the active layer.

The cover insulating film may include any one of silicon oxide (SiOx) and aluminum oxide (Al2O3).

The first cover layer is thinner than the active layer, and the first cover layer may have a thickness of 1 to 3 nm.

The cover insulating film may have a thickness of 2 to 5 nm.

The first cover layer may have a resistivity of 100 to 1,000 Ω·cm.

The thin film transistor further includes a gate insulating film disposed between the first cover layer and the gate electrode, and the resistivity of the first cover layer may be greater than the resistivity of the active layer and lower than the resistivity of the gate insulating film.

The thin film transistor further includes a source electrode and a drain electrode spaced apart from each other and respectively connected to the active layer, and the source electrode and the drain electrode may contact the active layer through a contact hole penetrating the cover insulating film and the first cover layer.

When the longitudinal direction of the active layer is referred to as the first direction and the direction perpendicular to the first direction is referred to as the second direction, the first cover layer includes a first side cover layer covering one side of the active layer with respect to the second direction; and a second side cover layer covering the other side of the active layer with respect to the second direction, wherein the first side cover layer and the second side cover layer may be spaced apart from each other.

The thin film transistor further includes a second cover layer in contact with the bottom surface of the active layer, wherein the second cover layer includes an oxide semiconductor material and may have a resistivity greater than that of the active layer.

The second cover layer includes an oxide semiconductor material, and the second cover layer includes at least one of an IGZO (InGaZnO)-based oxide semiconductor material, an IGO (InGaO)-based oxide semiconductor material, an IGZTO (InGaZnSnO)-based oxide semiconductor material, a GZTO (GaZnSnO)-based oxide semiconductor material, a GZO (GaZnO)-based oxide semiconductor material, and a GO (GaO)-based oxide semiconductor material, and the second cover layer can have a higher concentration of oxygen atom than the active layer.

The second cover layer is patterned, and the second cover layer can contact the first cover layer.

The second cover layer has a thinner thickness than the active layer, and the second cover layer can have a thickness of 1 to 3 nm.

An embodiment of the present disclosure comprises the steps of forming an active layer; forming a cover insulating film on the active layer; forming a first cover layer on the cover insulating film; And a step of forming a gate electrode on the first cover layer, and the step of forming the active layer and the cover insulating film includes a step of sequentially depositing the oxide semiconductor material layer and the cover insulating material layer; and a step of concurrently (and in some cases, simultaneously) wet-etching the oxide semiconductor material layer and the cover insulating material layer, wherein the first cover layer covers the top surface of the cover insulating film and the side surface of the active layer, and the first cover layer includes an oxide semiconductor material and has a resistivity greater than that of the active layer.

The first cover layer includes an oxide semiconductor material, and the first cover layer includes at least one of an IGZO (InGaZnO)-based oxide semiconductor material, an IGO (InGaO)-based oxide semiconductor material, an IGZTO (InGaZnSnO)-based oxide semiconductor material, a GZTO (GaZnSnO)-based oxide semiconductor material, a GZO (GaZnO)-based oxide semiconductor material, and a GO (GaO)-based oxide semiconductor material, and the first cover layer can have a higher concentration of oxygen atom than the active layer.

Another embodiment of the present disclosure provides a display device including the thin film transistor.

### BRIEF DESCRIPTION OF THE SEVERAL VIEWS OF THE DRAWINGS

The above and other objects, features and other advantages of the present disclosure will be more clearly understood from the following detailed description taken in conjunction with the accompanying drawings, in which:

FIG. 1 is a plan view of a thin film transistor according to an embodiment of the present disclosure.

FIG. 2 is a cross-sectional view taken along line I-I′ of FIG. 1.

FIG. 3 is a cross-sectional view taken along line II-II′ of FIG. 1.

FIG. 4 is a plan view of a thin film transistor according to another embodiment of the present disclosure.

FIG. 5 is a cross-sectional view taken along line III-III′ of FIG. 4.

FIG. 6 is a cross-sectional view taken along line IV-IV′ of FIG. 4.

FIG. 7 is a cross-sectional view of a thin film transistor according to another embodiment of the present disclosure.

FIG. 8 is a cross-sectional view of a thin film transistor according to another embodiment of the present disclosure.

FIG. 9 is a cross-sectional view of a thin film transistor according to another embodiment of the present disclosure.

FIG. 10 is a cross-sectional view of a thin film transistor according to another embodiment of the present disclosure.

FIGS. 11a to 11f are process diagrams showing a method of manufacturing a thin film transistor according to an embodiment of the present disclosure.

FIG. 12 is a schematic diagram of a display device according to one embodiment of the present disclosure.

FIG. 13 is a circuit diagram for one pixel of FIG. 12.

FIG. 14 is a plan view of the pixel of FIG. 13.

FIG. 15 is a cross-sectional view taken along line V-V′ of FIG. 14.

### DETAILED DESCRIPTION

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout the specification. In the following description, when the detailed description of the relevant known function or configuration is determined to unnecessarily obscure the important point of the present disclosure, the detailed description will be omitted.

In a case where ‘comprise,’ ‘have’ and ‘include’ described in the present disclosure are used, another portion may be added unless ‘only˜’ is used. The terms of a singular form may include plural forms unless referred to the contrary.

In construing an element, the element is construed as including an error band although there is no explicit description.

In describing a position relationship, for example, when the position relationship is described as ‘upon˜,’ ‘above˜,’ ‘below˜’ and ‘next to˜,’ one or more portions may be disposed between two other portions unless ‘just’ or ‘direct’ is used.

Spatially relative terms such as “below,” “beneath,” “lower,” “above,” and “upper” may be used herein to easily describe a relationship of one element or elements to another element or elements as illustrated in the drawings. It will be understood that these terms are intended to encompass different orientations of the device in addition to the orientation depicted in the drawings. For example, if the device illustrated in the figure is reversed, the device described to be arranged “below,” or “beneath” another device may be arranged “above” another device. Therefore, an exemplary term “below or beneath” may include “below or beneath” and “above” orientations. Likewise, an exemplary term “above” or “on” may include “above” and “below or beneath” orientations.

In describing a temporal relationship, for example, when the temporal order is described as “after,” “subsequent,” “next,” and “before,” a case which is not continuous may be included, unless “just” or “direct” is used.

As used herein, the terms “connected” and “coupled” are intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner. For example, the term “in contact with,” as used herein, encompasses both “indirect contact” and “direct contact.” Accordingly, when the phrase “A is in contact with B” is used, it implies that other components may be present between A and B, unless explicitly specified as “A is in direct contact with B.”

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” may include all combinations of two or more elements selected from the first, second and third elements as well as each element of the first, second and third elements. Namely, the text “at least one of A and B” as used herein should be understood to include at least one of A, or at least one of B, or at least one of both A and B. This similarly applies to “at least one of A, B, and C” and so forth.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

In the addition of reference numerals to the components of each drawing describing embodiments of the present disclosure, the same components can have the same sign as can be displayed on the other drawings.

In the embodiments of the present disclosure, a source electrode and a drain electrode are distinguished for convenience of description, and the source electrode and the drain electrode may be interchanged. The source electrode may be the drain electrode and vice versa. In addition, the source electrode of any one embodiment may be a drain electrode in another embodiment, and the drain electrode of any one embodiment may be a source electrode in another embodiment.

In some embodiments of the present disclosure, for convenience of description, a source area is distinguished from a source electrode, and a drain area is distinguished from a drain electrode, but embodiments of the present disclosure are not limited thereto. The source area may be the source electrode, and the drain area may be the drain electrode. In addition, the source area may be the drain electrode, and the drain area may be the source electrode.

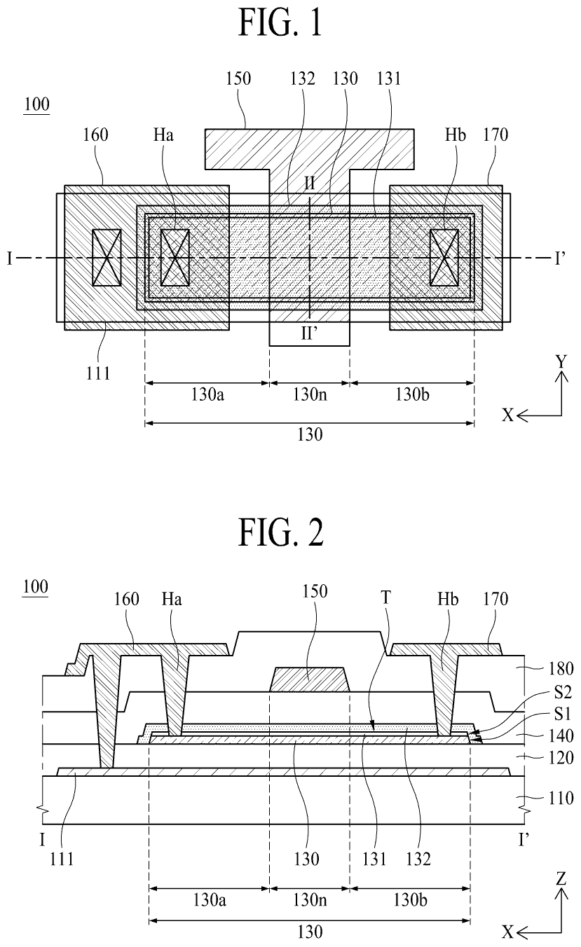

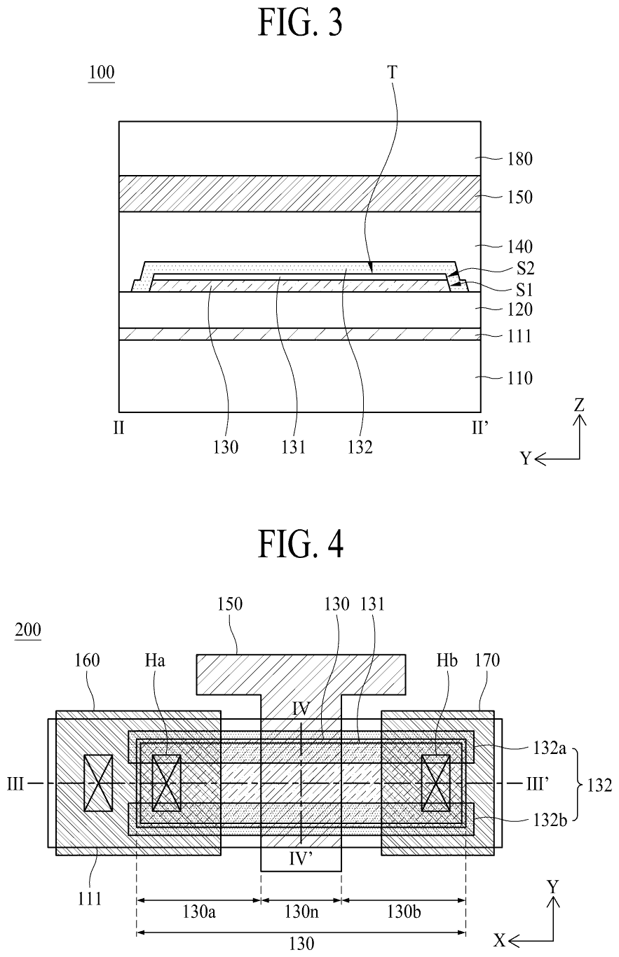

FIG. 1 is a plan view of a thin film transistor 100 according to one embodiment of the present disclosure. FIG. 2 is a cross-sectional view taken along line I-I′ of FIG. 1. FIG. 3 is a cross-sectional view taken along line II-II′ of FIG. 1.

Referring to FIGS. 1, 2, and 3, a thin film transistor 100 according to one embodiment of the present disclosure may include an active layer 130, a cover insulating film 131, a first cover layer 132, and a gate electrode 150.

Specifically, referring to FIGS. 1, 2, and 3, the thin film transistor may include an active layer 130 on a base substrate 110, a cover insulating film 131 on the active layer 130, a first cover layer 132 on the cover insulating film 131, and a gate electrode 150 spaced apart from the active layer 130 and overlapping at least partly with the active layer 130.

According to one embodiment of the present disclosure, the thin film transistor 100 may further include a base substrate 110. Referring to FIGS. 2 and 3, the active layer 130 is disposed on the base substrate 110.

According to one embodiment of the present disclosure, the thin film transistor 100 may further include a buffer layer 120. Referring to FIGS. 2 and 3, the active layer 130 is disposed on the buffer layer 120. Specifically, the buffer layer 120 is disposed between the base substrate 110 and the active layer 130.

According to one embodiment of the present disclosure, the thin film transistor 100 may further include a gate insulating film 140. Referring to FIGS. 2 and 3, the gate insulating film 140 is disposed on the active layer 130. Specifically, the gate insulating film 140 is disposed between the active layer 130 and the gate electrode 150.

According to one embodiment of the present disclosure, the thin film transistor 100 may further include an interlayer insulating film 180. Referring to FIGS. 2 and 3, the interlayer insulating film 180 is disposed on the gate electrode 150. Specifically, the gate electrode 150 is disposed between the gate insulating film 140 and the interlayer insulating film 180.

According to one embodiment of the present disclosure, the thin film transistor 100 may further include a source electrode 160 and a drain electrode 170. Referring to FIGS. 1 and 2, the source electrode 160 and the drain electrode 170 are disposed on the interlayer insulating film 180.

Hereinafter, components of the thin film transistor 100 according to one embodiment of the present disclosure will be described in more detail.

The base substrate 110 may be made of glass or plastic. A transparent plastic having flexible properties, such as polyimide, may be used.

When polyimide is used as the base substrate 110, considering that a high-temperature deposition process is performed on the base substrate 110, a heat-resistant polyimide that can withstand high temperatures may be used. In this case, in order to form a thin film transistor, a deposition, etching, and other processes may be performed while the polyimide substrate is placed on a carrier substrate made of a highly durable material such as glass.

Referring to FIGS. 2 and 3, a buffer layer 120 may be disposed on the base substrate 110.

The buffer layer 120 is formed on the base substrate 110 and may be formed of an inorganic material or an organic material. For example, it may include an insulating oxide such as silicon oxide (SiOx) or aluminum oxide (Al2O3).

The buffer layer 120 protects the active layer 130 by blocking impurities such as moisture and oxygen flowing in from the base substrate 110 and serves to flatten the upper portion of the base substrate 110, and may be formed as a single layer or multiple layers.

Referring to FIGS. 2 and 3, the active layer 130 may be disposed on the buffer layer 120.

The active layer 130 may include a channel portion 130n, a first connection portion 130a, and a second connection portion 130b.

Specifically, the active layer 130 may include a channel portion 130n that overlaps at least partially with the gate electrode 150 in a plane, a first connecting portion 130a that does not overlap with the gate electrode 150 in a plane and is connected to one side of the channel portion 130n, and a second connecting portion 130b that does not overlap with the gate electrode 150 in a plane and is connected to the other side of the channel portion 130n.

According to one embodiment of the present disclosure, the first connecting portion 130a and the second connecting portion 130b are spaced apart from each other with the channel portion 130n therebetween.

According to one embodiment of the present disclosure, the active layer 130 may be formed by a semiconductor material. The active layer 130 may comprise an oxide semiconductor material.

The oxide semiconductor material may be, for example, an InZnO (IZO)-based oxide semiconductor material, an InGaO (IGO)-based oxide semiconductor material, an ITO (InSnO)-based oxide semiconductor material, an IGZO (InGaZnO)-based oxide semiconductor material, an IGZTO (InGaZnSnO)-based oxide semiconductor material, GZTO (GaZnSnO)-based oxide semiconductor material, GZO (GaZnO)-based oxide semiconductor material, ITZO (InSnZnO)-based oxide semiconductor material, and FIZO (FeInZnO)-based oxide semiconductor material. However, one embodiment of the present disclosure is not limited to these, and the active layer 130 may be made of other oxide semiconductor materials known in the art.

The first connecting portion 130a and the second connecting portion 130b may be formed by selective conductorization of the active layer 130 made of a semiconductor material. According to one embodiment of the present disclosure, imparting conductivity to certain regions of the active layer 130 so that it can act as a conductor is referred to as selective conductorization.

For example, the active layer 130 may be selectively conductive by ion doping. As a result, the first connecting portion 130a and the second connecting portion 130b may be formed. However, one embodiment of the present disclosure is not limited to this, and the active layer 130 may be selectively conductorization by other methods known in the art.

The first connecting portion 130a and second connecting portion 130b do not overlap with the gate electrode 150. The first connecting portion 130a and the second connecting portion 130b have good electrical conductivity and high mobility compared to the channel portion 130n. Therefore, the first connecting portion 130a and the second connecting portion 130b can serve as wiring, respectively.

According to one embodiment of the present disclosure, the active layer 130 may have a multi-layer structure. For example, although not shown in the drawings, the active layer 130 may include a first active layer and a second active layer.

The first active layer and the second active layer may comprise the same semiconductor material, or may comprise different semiconductor materials.

According to one embodiment of the present disclosure, the thin film transistor 100 may include a cover insulating film 131 on the active layer 130.

Referring to FIGS. 1, 2, and 3, the cover insulating film 131 is disposed between the active layer 130 and the gate electrode 150. Specifically, the cover insulating film 131 is disposed between the active layer 130 and the gate insulating film 140.

According to one embodiment of the present disclosure, the cover insulating film 131 is patterned and formed on the active layer 130. Specifically, the cover insulating film 131 is formed by wet etching at the same time as the active layer 130.

According to one embodiment of the present disclosure, the cover insulating film 131 may be formed from an inorganic material or an organic material. For example, it may comprise an insulating oxide such as silicon oxide (SiOx), aluminum oxide (Al2O3), or the like. Preferably, the cover insulating film 131 may comprise silicon oxide (SiOx).

The cover insulating film 131 may be disposed on the active layer 130 to protect the upper interface of the active layer 130. Specifically, the entire area of the cover insulating film 131 may be disposed on the active layer 130 to protect the upper interface of the active layer 130 from impurities such as moisture, oxygen, and the like introduced from the outside.

According to one embodiment of the present disclosure, the cover insulating film 131 may have a thickness of 2 to 5 nm. Specifically, when the cover insulating film 131 has a thickness of 2 to 5 nm, the upper interface of the active layer 130 can be protected from the outside, and can be etched concurrently (and in some cases, simultaneously) with the active layer 130 by an etchant.

If the cover insulating film 131 has a thickness of less than 2 nm, the cover insulating film 131 may not sufficiently protect the upper interface of the active layer 130 due to its small thickness. Further, if the thickness of the cover insulating film 131 is less than 2 nm, process stability may be compromised when forming the cover insulating film 131.

Furthermore, if the thickness of the cover insulating film 131 is greater than 5 nm, it may be difficult to etch the cover insulating film 131 concurrently (and in some cases, simultaneously) with the active layer 130 by an etchant. Specifically, when the thickness of the cover insulating film 131 exceeds 5 nm, simultaneous wet etching of the active layer 130 and the cover insulating film 131 by the etchant may result in a problem of residual film of the cover insulating film 131 remaining.

According to one embodiment of the present disclosure, a first cover layer 132 is disposed on the cover insulating film 131.

Specifically, referring to FIGS. 1, 2, and 3, the thin film transistor 100 may further include a first cover layer 132 disposed on the cover insulating film 131. More specifically, the first cover layer 132 is disposed between the cover insulating film 131 and the gate insulating film 140.

According to one embodiment of the present disclosure, the first cover layer 132 may cover the top surface T of the cover insulating film 131 and the side S1 (or the side surface S1) of the active layer 130.

Referring to FIGS. 2 and 3, the first cover layer 132 can cover the top surface T of the cover insulating film 131 and the side S1 of the active layer 130.

Specifically, when the longitudinal direction of the active layer 130 is referred to as the first direction X and the direction perpendicular to the first direction Y is referred to as the second direction Y, the first cover layer 132 may cover the side S1 of the active layer 130 relative to the first direction X and the second direction Y.

In this case, the first direction X corresponds to the direction of the line segment connecting the first connecting portion 130a and the second connecting portion 130b of the active layer 130 at the shortest distance. This first direction X may be referred to as the longitudinal direction of the active layer 130, and may also be referred to as the longitudinal direction of the channel portion 130n.

FIG. 2 illustrates a first cover layer 132 covering a side S1 of the active layer 130 relative to the first direction X.

In FIG. 3, the first cover layer 132 is shown covering the side S1 of the active layer 130 in a second direction (Y).

The second direction Y is a direction perpendicular to the first direction X. This second direction Y may be referred to as the width direction of the active layer 130, and may also be referred to as the width direction of the channel portion 130n.

According to one embodiment of the present disclosure, the first cover layer 132 may contact the top surface T of the cover insulating film 131 and the side S1 of the active layer 130. Specifically, the first cover layer 132 may also be in contact with the side S2 (or the side surface S2) of the cover insulating film 131.

FIGS. 2 and 3 illustrate a configuration in which the first cover layer 132 is in contact with the side S1 of the active layer 130 and the side S2 of the cover insulating film 131 concurrently (and in some cases, simultaneously).

According to one embodiment of the present disclosure, the first cover layer 132 may comprise an oxide semiconductor material and may have a resistivity greater than the active layer 130.

Specifically, the first cover layer 132 may include at least one of an IGZO (InGaZnO)-based oxide semiconductor material, an IGO (InGaO)-based oxide semiconductor material, an IGZTO (InGaZnSnO)-based oxide semiconductor material, a GZTO (GaZnSnO)-based oxide semiconductor material, a GZO (GaZnO)-based oxide semiconductor material, and a GO (GaO)-based oxide semiconductor material.

The first cover layer 132, according to one embodiment of the present disclosure, comprises an oxide semiconductor material, but has electrical properties close to those of an insulating layer.

According to one embodiment of the present disclosure, the first cover layer 132 has a resistivity greater than the active layer 130. The first cover layer 132 is not disposed to increase the carrier concentration or mobility of the active layer 130, but rather to prevent the increase of defects in the active layer due to chemical damage of the etchant and to reduce the influence of hydrogen.

In order not to affect the electrical properties of the active layer 130, the first cover layer 132 has a greater resistivity than the active layer 130.

According to one embodiment of the present disclosure, the first cover layer 132 has a higher concentration of oxygen atom than the active layer 130. By increasing the partial pressure of oxygen during the manufacturing step of the first cover layer 132, the first cover layer 132 can be made to contain a high concentration of oxygen.

By having the first cover layer 132 have a higher concentration of oxygen atom than the active layer 130, the first cover layer 132 can have a greater resistivity than the active layer 130.

In general, chemical damage by the etchant during patterning on the active layer may increase defects in the active layer. Specifically, the defects may increase in the width direction of the active layer.

Furthermore, an active layer comprising an oxide semiconductor material may be subject to the influence of hydrogen introduced from the outside, which increases the depth of conductorization penetration and reduces the length of the effective channel, thereby reducing the driving stability of the device.

To address these issues, the first cover layer 132 according to one embodiment of the present disclosure has a higher resistivity than the active layer 130 and covers the sides of the active layer 130, which can prevent an increase in defects in the active layer 130 due to wet etch.

Further, by having the first cover layer 132 have a higher concentration of oxygen atoms than the active layer 130, the oxygen vacancies that cause defects in the active layer 130 can be compensated for, thereby improving the reliability of the thin film transistor.

Furthermore, when the first cover layer 132 according to one embodiment of the present disclosure comprises an oxide semiconductor material, the first cover layer 132 may have an excellent hydrogen adsorption capacity, thereby reducing the influence of hydrogen introduced from the outside.

Specifically, the first cover layer 132 may have a resistivity of 100 to 1,000 Ω·cm.

For example, if the resistivity of the first cover layer 132 is less than 100 Ω·cm, some current may flow through the first cover layer 132 even when the thin film transistor is off, resulting in leakage current.

Furthermore, given that the first cover layer 132 is made of an oxide semiconductor material, it may be difficult to implement the first cover layer 132 to have a resistivity in excess of 1,000 Ω·cm.

According to one embodiment of the present disclosure, the resistivity of the first cover layer 132 may be greater than the resistivity of the active layer 130 and less than the resistivity of the gate insulating film 140.

For example, the resistivity of the first cover layer 132 may be 100 times or more compared to the resistivity of the active layer 130.

For example, the resistivity of the active layer 130 may be 10-3 to 1 Ω·cm, and the resistivity of the gate insulating film 140 may be 1015 to 1018 Ω·cm, according to one embodiment of the present disclosure.

According to one embodiment of the present disclosure, the first cover layer 132 may have a smaller thickness than the active layer 130. Because the first cover layer 132 is formed with a thickness less than the active layer 130, changes in the electrical properties of the first cover layer 132 do not affect the electrical properties of the active layer 130.

As such, the first cover layer 132 serves to protect the active layer 130 and the channel portion 130n from external factors.

According to one embodiment of the present disclosure, the first cover layer 132 may have a thickness of 1 to 3 nm.

If the first cover layer 132 has a thickness of less than 1 nm, the first cover layer 132 may not sufficiently protect the active layer 130. Further, if the first cover layer 132 has a thickness of less than 1 nm, the process stability for forming the first cover layer 132 may be compromised.

Furthermore, if the thickness of the first cover layer 132 is greater than 3 nm, the resistance of the first cover layer 132 may be lowered, resulting in increased leakage current. As a result, a problem of degradation of the thin film transistor 100 during on/off may occur, and as a result, the stability of the thin film transistor 100 may be reduced.

According to one embodiment of the present disclosure, the thin film transistor 100 may further include a gate insulating film 140 between the active layer 130 and the gate electrode 150. Specifically, the gate insulating film 140 is disposed between the first cover layer 132 and the gate electrode 150. More specifically, the gate insulating film 140 may cover the entire top surface of the active layer 130. FIG. 2 illustrates a configuration in which the gate insulating film 140 covers the entire top surface of the active layer 130.

However, one embodiment of the present disclosure is not limited thereto, and the first connecting portion 130a and the second connecting portion 130b of the active layer 130 may be exposed from a gate insulating film 140.

The gate insulating film 140 may comprise at least one of a silicon oxide, a silicon nitride, and a metal-based oxide. The gate insulating film 140 may have a monolayer structure, or may have a multilayer structure. The gate insulating film 140 protects the channel portion 130n.

Referring to FIG. 2, a gate electrode 150 is disposed on the gate insulating film 140. The gate electrode 150 overlaps the channel portion 130n of the active layer 130.

The gate electrode 150 can include at least one of an aluminum-based metal, such as aluminum (Al) or an aluminum alloy, a silver-based metal, such as silver (Ag) or a silver alloy, a copper-based metal, such as copper (Cu) or a copper alloy, a molybdenum-based metal, such as molybdenum (Mo) or a molybdenum alloy, chromium (Cr), tantalum (Ta), neodymium (Nd), and titanium (Ti). The gate electrode 150 may also have a multilayer film structure comprising at least two conductive films having different physical properties.

Referring to FIG. 2, an interlayer insulating film 180 is disposed on the gate electrode 150 and the gate insulating film 140. The interlayer insulating film 180 is an insulating layer made of an insulating material. The interlayer insulating film 180 may be made of an organic material, an inorganic material, or a laminate of an organic layer and an inorganic layer.

Referring to FIG. 2, a source electrode 160 and a drain electrode 170 are disposed on the interlayer insulating layer 180.

Although not shown, the source electrode 160 and drain electrode 170 may be disposed on the gate insulating film 140 and may be disposed on the same layer as the gate electrode 150. The source electrode 160 and drain electrode 170 can be made of the same material as the gate electrode 150 and by the same process.

Each of the source electrode 160 and the drain electrode 170 may include at least one of the following metals: an aluminum-based metal, such as aluminum (Al) or an aluminum alloy, a silver-based metal, such as silver (Ag) or a silver alloy, a copper-based metal, such as copper (Cu) or a copper alloy, a molybdenum-based metal, such as molybdenum (Mo) or a molybdenum alloy, chromium (Cr), tantalum (Ta), neodymium (Nd), and titanium (Ti). The source electrode 160 and the drain electrode 170 may each have a multilayer film structure comprising at least two conductive films having different physical properties.

Referring to FIGS. 1 and 2, the source electrode 160 and the drain electrode 170 are connected to the active layer 130 via contact holes Ha, Hb that penetrate the cover insulating film 131 and the first cover layer 132, respectively. Specifically, the source electrode 160 and the drain electrode 170 are connected to the active layer 130 by contacting the first connecting portion 130a and the second connecting portion 130b, respectively.

Referring to FIGS. 1, 2, and 3, a light shielding layer 111 may be disposed on the base substrate 110. Specifically, the light shielding layer 111 may be disposed between the base substrate 110 and the active layer 130. The light shielding layer 111 overlaps the channel portion 130n. The light shielding layer 111 protects the channel portion 130n by blocking light incident from the outside.

The light shielding layer 111 may be made of a material having light-blocking properties. The light shielding layer 111 may comprise at least one of an aluminum-based metal, such as aluminum (Al) or an aluminum alloy, a molybdenum-based metal, such as molybdenum (Mo) or a molybdenum alloy, chromium (Cr), tantalum (Ta), neodymium (Nd), titanium (Ti), and iron (Fc). According to one embodiment of the present disclosure, the light shielding layer 111 may be electrically conductive.

The light shielding layer 111 may be omitted. Although not shown in FIGS. 1, 2, and 3, a buffer layer may additionally be disposed between the base substrate 110 and the light shielding layer 111. The light shielding layer 111 may be electrically connected to any one of the source electrode 160 and the drain electrode 170. FIG. 2 illustrates a configuration in which the light shielding layer 111 is electrically connected to the source electrode 160.

According to one embodiment of the disclosure, the first cover layer 132 may include a first side cover layer 132a covering one side of the active layer 130 relative to the second direction Y and a second side cover layer 132b covering the other side of the active layer 130 relative to the second direction Y.

FIGS. 4 and 6 illustrate the first side cover layer 132a and the second side cover layer 132b covering a side S1 of the active layer 130 relative to the second direction (Y).

According to one embodiment of the present disclosure, the first side cover layer 132a and the second side cover layer 132b are spaced apart from each other. Specifically, the first side cover layer 132a and the second side cover layer 132b are spaced apart with a portion of the channel portion 130n between in a plane.

In the region where the first side cover layer 132a and the second side cover layer 132b are spaced apart, the first cover layer 132 is not disposed so that the cover insulating film 131 and the gate insulating film 140 are in contact. In FIG. 6, the cover insulating film 131 and the gate insulating film 140 are shown in contact in a region where the first side cover layer 132a and the second side cover layer 132b are spaced apart.

According to one embodiment of the present disclosure, the first side cover layer 132a and the second side cover layer 132b each overlap the active layer 130 extending from the first connecting portion 130a to the second connecting portion 130b along the first direction X.

FIGS. 4, 5, and 6 show a portion of the first cover layer 132 disposed on the top surface T of the cover insulating film 131 is patterned compared to FIGS. 1, 2, and 3.

Referring to FIGS. 4, 5, and 6, the first side cover layer 132a and the second side cover layer 132b cover the side S1 of the active layer 130, which can prevent an increase in defects in the active layer due to chemical damage of the etchant on the side S1 of the active layer 130.

Furthermore, referring to FIGS. 4, 5, and 6, even if a portion of the first cover layer 132 disposed on the top surface T of the cover insulating film 131 is patterned, the role of protecting the side S1 of the active layer 130 by the first side cover layer 132a and the second side cover layer 132b can be equally fulfilled.

According to one embodiment of the present disclosure, a second cover layer 133 may be disposed between the buffer layer 120 and the active layer 130.

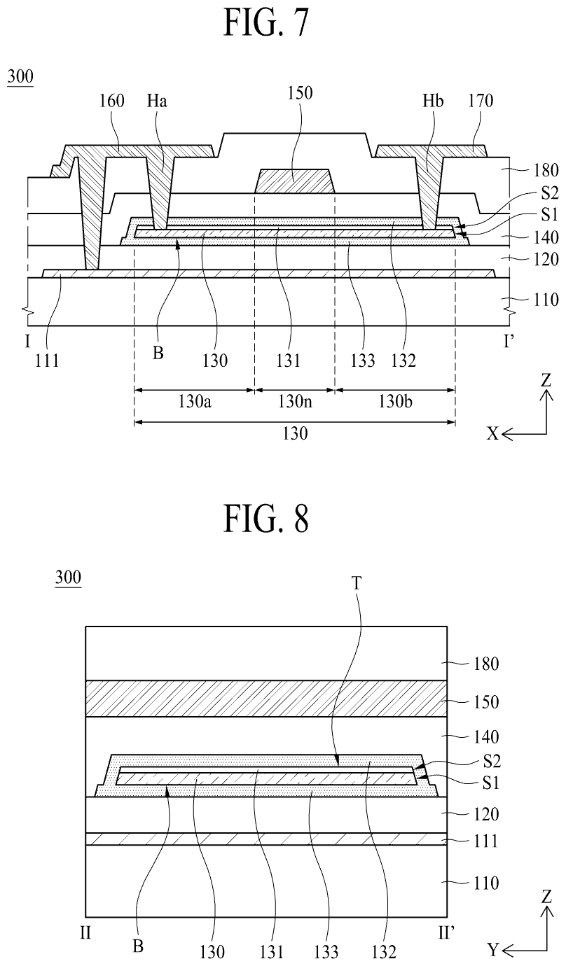

FIG. 7 is a cross-sectional view of a thin film transistor 300 according to another embodiment of the present disclosure. Specifically, the cross-section in FIG. 7 corresponds to the cross-section cut along I-I′ in FIG. 1. More specifically, the cross-section of FIG. 7 corresponds to the cross-section of FIG. 2.

FIG. 8 is a cross-sectional view of a thin film transistor 300, according to another embodiment of the present disclosure. Specifically, the cross-section of FIG. 8 corresponds to the cross-section cut along II-II′ of FIG. 1. More specifically, the cross-section of FIG. 8 corresponds to the cross-section of FIG. 3.

Compared to FIGS. 2 and 3, FIGS. 7 and 8 further include a second cover layer 133 in contact with the bottom surface B of the active layer 130.

According to one embodiment of the present disclosure, the second cover layer 133 comprises an oxide semiconductor material. Specifically, the second cover layer 133 may include at least one of an IGZO (InGaZnO)-based oxide semiconductor material, an IGO (InGaO)-based oxide semiconductor material, an IGZTO (InGaZnSnO)-based oxide semiconductor material, a GZTO (GaZnSnO)-based oxide semiconductor material, a GZO (GaZnO)-based oxide semiconductor material, and a GO (GaO)-based oxide semiconductor material.

The second cover layer 133 may be formed of the same oxide semiconductor material as the first cover layer 132, or may be formed of a different oxide semiconductor material than the first cover layer 132.

According to one embodiment of the present disclosure, the second cover layer 133 may include an oxide semiconductor material and may have a resistivity greater than the active layer 130.

Specifically, the second cover layer 133 may have a resistivity of 100 to 1,000 Ω·cm.

For example, if the second cover layer 133 has a resistivity of less than 100 Ω·cm, some current may flow through the second cover layer 133 even when the thin film transistor is off, resulting in leakage current.

Furthermore, given that the second cover layer 133 is made of an oxide semiconductor material, it may be difficult to implement the second cover layer 133 to have a resistivity in excess of 1,000 Ω·cm.

According to one embodiment of the present disclosure, the second cover layer 133 has a resistivity greater than the active layer 130. The second cover layer 133 is not disposed to increase the carrier concentration or mobility of the active layer 130, but rather to block hydrogen diffusing from layers disposed on the underside of the active layer 130.

Specifically, by having a higher concentration of oxygen atoms than the active layer 130, the second cover layer 133 can compensate for oxygen vacancies that cause defects in the active layer 130, thereby improving the reliability of the thin film transistor.

Furthermore, when the second cover layer 133 according to one embodiment of the present disclosure comprises an oxide semiconductor material, the second cover layer 133 may have an excellent hydrogen adsorption capacity, thereby reducing the influence of hydrogen introduced from the outside. For example, the influence of hydrogen diffusing from the buffer layer 120 disposed on the lower part of the active layer 130 can be reduced.

According to one embodiment of the present disclosure, the second cover layer 133 may be thinner than the active layer 130. Since the second cover layer 133 is formed with a thickness less than the active layer 130, changes in the electrical properties of the second cover layer 133 do not affect the electrical properties of the active layer 130.

As such, the second cover layer 133 serves to protect the active layer 130 and the channel portion 130n from external factors.

According to one embodiment of the present disclosure, the second cover layer 133 may have a thickness of 1 to 3 nm.

If the second cover layer 133 has a thickness of less than 1 nm, the second cover layer 133 may not sufficiently protect the active layer 130. Further, if the second cover layer 133 has a thickness of less than 1 nm, the process stability for forming the second cover layer 133 may be compromised.

Further, if the thickness of the second cover layer 133 is greater than 3 nm, charge flow through the second cover layer 133 may occur.

Referring to FIGS. 7 and 8, the second cover layer 133 may extend outside of the active layer 130.

Specifically, the second cover layer 133 may contact the first cover layer 132 at an end of the active layer 130. For example, the second cover layer 133 may be patterned.

By contacting the first cover layer 132 and the second cover layer 133 at the ends, an increase in defects in the active layer 130 due to chemical damage of the etchant at the side S1 of the active layer 130 can be prevented.

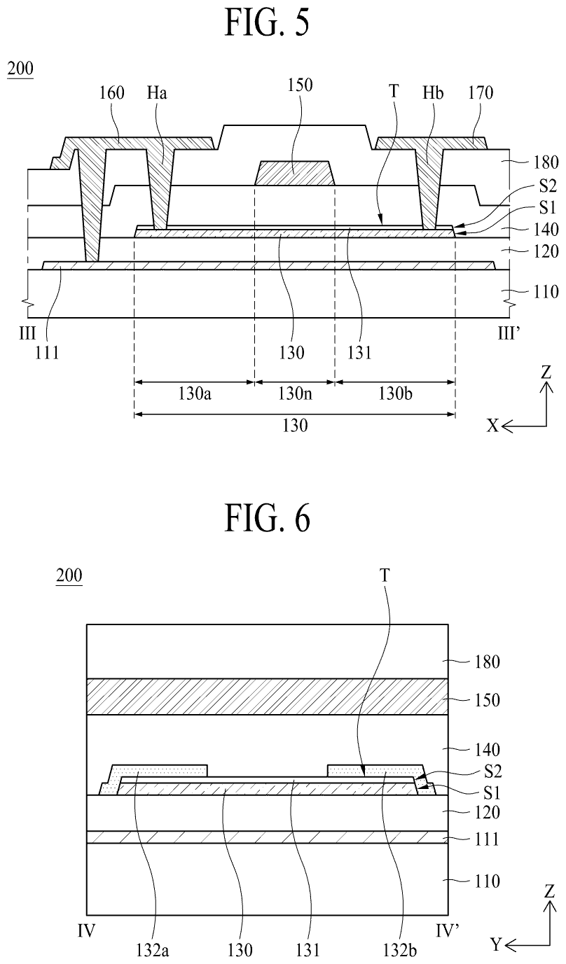

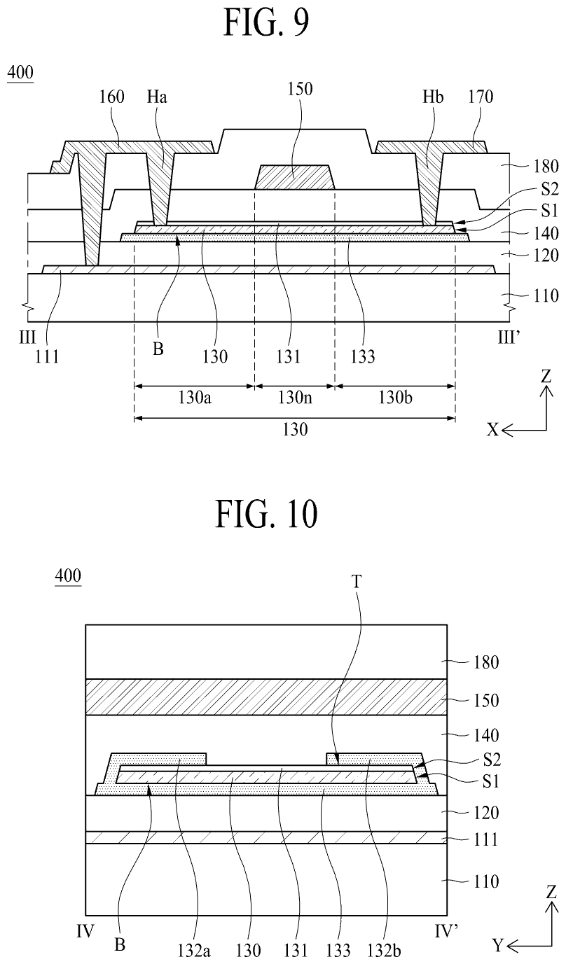

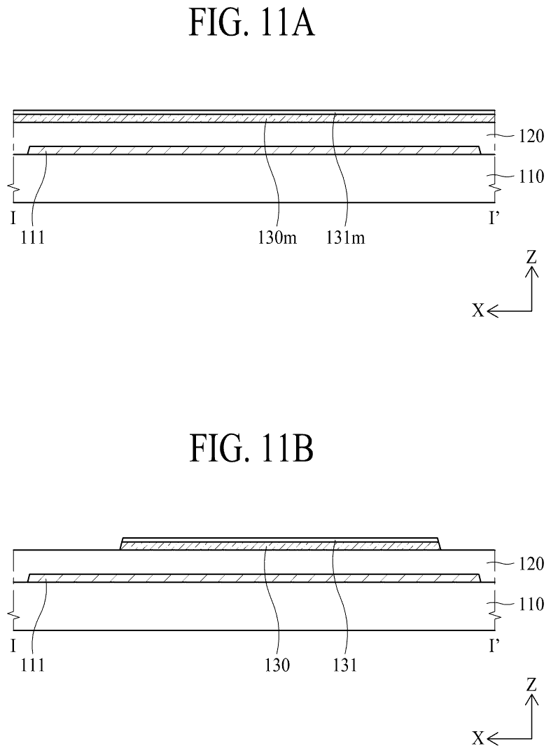

FIG. 9 is a cross-sectional view of a thin film transistor 400, according to another embodiment of the present disclosure. Specifically, the cross-section of FIG. 9 corresponds to the cross-section cut along III-III′ of FIG. 4. More specifically, the cross-sectional view of FIG. 9 corresponds to the cross-sectional view of FIG. 5.

FIG. 10 is a cross-sectional view of a thin film transistor 400, according to another embodiment of the present disclosure. Specifically, the cross-section of FIG. 10 corresponds to the cross-section cut along IV-IV′ of FIG. 4. More specifically, the cross-section of FIG. 10 corresponds to the cross-section of FIG. 6.

Compared to FIGS. 5 and 6, FIGS. 9 and 10 further include a second cover layer 133 in contact with the bottom surface B of the active layer 130.

Description of the second cover layer 133 is redundant and omitted.

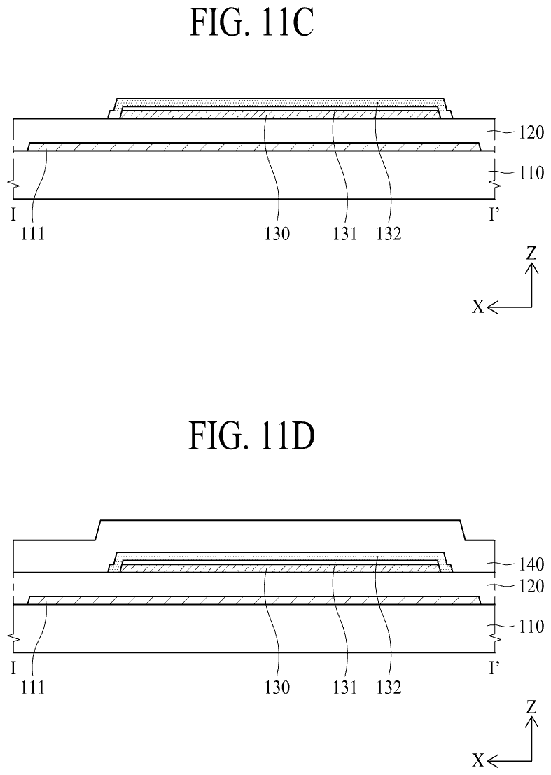

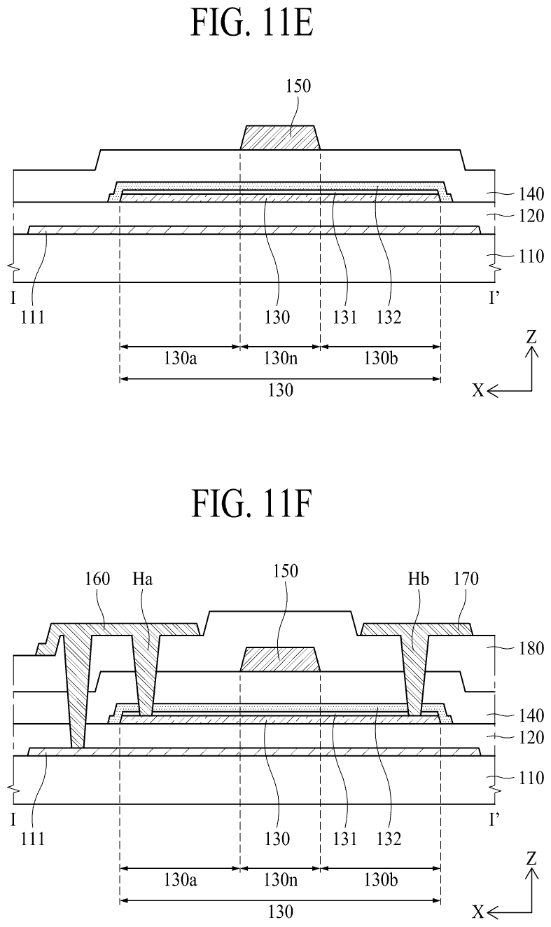

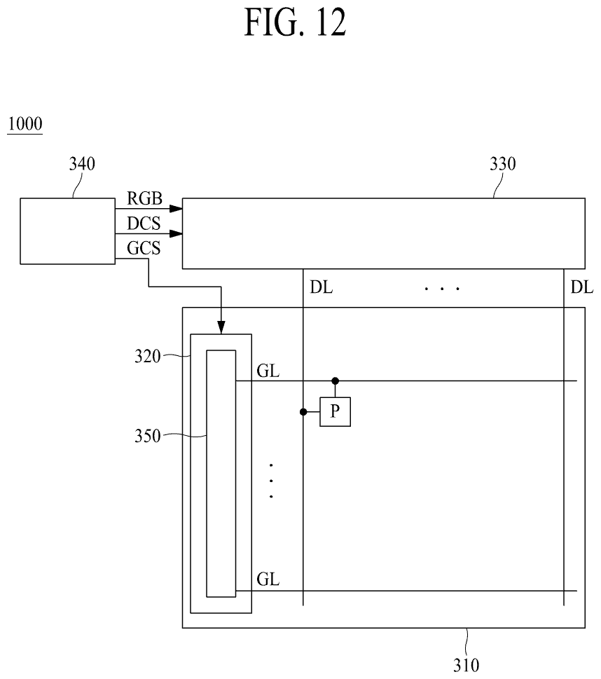

FIGS. 11A through 11F are process diagrams illustrating a method of manufacturing a thin film transistor according to one embodiment of the present disclosure.

The cross-sections of FIGS. 11a through 11f correspond to the cross-sections cut along I-I′ in FIG. 1. More specifically, the cross-sections of FIGS. 11a through 11f correspond to the cross-sections of FIG. 2.

According to one embodiment of the present disclosure, a method of manufacturing a thin film transistor includes the steps of forming an active layer 130, forming a cover insulating film 131 on the active layer 130, forming a first cover layer 132 on the cover insulating film 131, and forming a gate electrode 150 on the first cover layer 132.

FIG. 11A illustrates sequentially arranging a base substrate 110, a light shielding layer 111, and a buffer layer 120, and sequentially depositing an oxide semiconductor material layer 130m and a cover insulating material layer 131m on the buffer layer 120.

In this case, the oxide semiconductor material layer 130m may include an oxide semiconductor material. The oxide semiconductor material may be, for example, an InZnO (IZO)-based oxide semiconductor material, an InGaO (IGO)-based oxide semiconductor material, an ITO (InSnO)-based oxide semiconductor material, an IGZO (InGaZnO)-based oxide semiconductor material, an IGZTO (InGaZnSnO)-based oxide semiconductor material, GZTO (GaZnSnO)-based oxide semiconductor material, GZO (GaZnO)-based oxide semiconductor material, ITZO (InSnZnO)-based oxide semiconductor material, and FIZO (FeInZnO)-based oxide semiconductor material. However, one embodiment of the present disclosure is not limited thereto.

The cover insulating material layer 131m may be formed of an inorganic material or an organic material. For example, it may comprise an insulating oxide such as silicon oxide (SiOx), aluminum oxide (Al2O3), or the like. Preferably, the cover insulating material layer 131m may comprise silicon oxide (SiOx).

FIG. 11B illustrates simultaneous wet etching of the oxide semiconductor material layer 130m and the cover insulating material layer 131m to form the active layer 130 and the cover insulating film 131.

FIG. 11C illustrates a first cover layer 132 being formed on the cover insulating film 131.

The first cover layer 132 contacts the top and sides of the cover insulating film 131 and contacts the sides of the active layer 130. Further, the first cover layer 132 may extend outside of the active layer 130.

FIG. 11D illustrates forming a gate insulating film 140 on the first cover layer 132. The gate insulating film 140 is formed on the entire surface of the first cover layer 132 and the buffer layer 120.

FIG. 11E shows a gate electrode 150 being formed on the gate insulating film 140.

Although not shown in FIG. 11E, doping is accomplished using the gate electrode 150 as a mask. As a result, the portion of the active layer 130 that overlaps the gate electrode 150 is undoped, which can become the channel portion 130n.

By doping with a dopant, the boundary of the channel portion 130n can be clarified. Furthermore, by doping with dopants, the regions of the active layer 130 that do not overlap with the gate electrode 150 may be conductorized and become the first connecting portion 130a and the second connecting portion 130b.

FIG. 11F illustrates an interlayer insulating film 180 being formed on the gate electrode 150, and a source electrode 160 and a drain electrode 170 being formed on the interlayer insulating film 180.

Descriptions of the interlayer insulating film 180, the source electrode 160, and the drain electrode 170 are redundant and omitted.

FIG. 12 is a schematic diagram illustrating a display apparatus 1000 according to further still another embodiment of the present disclosure.

As shown in FIG. 12, the display apparatus 1000 according to further still another embodiment of the present disclosure may include a display panel 310, a gate driver 320, a data driver 330 and a controller 340.

The display panel 310 includes gate lines GL and data lines DL, and pixels P are disposed in intersection areas of the gate lines GL and the data lines DL. An image is displayed by driving of the pixels P. The gate lines GL, the data lines DL and the pixels P may be disposed on the base substrate 110.

The controller 340 controls the gate driver 320 and the data driver 330.

The controller 340 outputs a gate control signal GCS for controlling the gate driver 320 and a data control signal DCS for controlling the data driver 330 by using a signal supplied from an external system not shown. Also, the controller 340 samples input image data input from the external system, realigns the sampled data and supplies the realigned digital image data RGB to the data driver 330.

The gate control signal GCS includes a gate start pulse GSP, a gate shift clock GSC, a gate output enable signal GOE, a start signal Vst and a gate clock GCLK. Also, control signals for controlling a shift register may be included in the gate control signal GCS.

The data control signal DCS includes a source start pulse SSP, a source shift clock signal SSC, a source output enable signal SOE and a polarity control signal POL.

The data driver 330 supplies a data voltage to the data lines DL of the display panel 310. In detail, the data driver 330 converts the image data RGB input from the controller 340 into an analog data voltage and supplies the data voltage to the data lines DL.

According to one embodiment of the present disclosure, the gate driver 320 may be packaged on the display panel 310. In this way, a structure in which the gate driver 320 is directly packaged on the display panel 310 will be referred to as a Gate In Panel (GIP) structure. In detail, in the Gate In Panel (GIP) structure, the gate driver 320 may be disposed on the base substrate 110.

The display apparatus 1000 according to one embodiment of the present disclosure may include the above-described thin film transistors 100, 200, 300, and 400. According to one embodiment of the present disclosure, the gate driver 320 may include the above-described thin film transistors 100, 200, 300, and 400.

The gate driver 320 may include a shift register 350.

The shift register 350 sequentially supplies gate pulses to the gate lines GL for one frame by using the start signal and the gate clock, which are transmitted from the controller 340. In this case, one frame means a time period at which one image is output through the display panel 310. The gate pulse has a turn-on voltage capable of turning on a switching device (thin film transistor) disposed in the pixel P.

Also, the shift register 350 supplies a gate-off signal capable of turning off the switching device, to the gate line GL for the other period of one frame, at which the gate pulse is not supplied. Hereinafter, the gate pulse and the gate-off signal will be collectively referred to as a scan signal SS or Scan.

The shift register 350 may include the above-described thin film transistors 100, 200, 300, and 400.

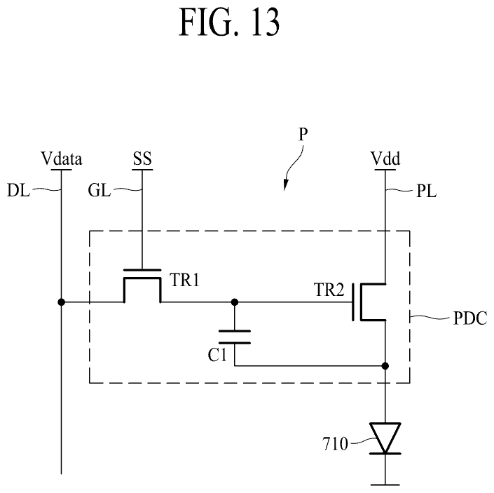

FIG. 13 is a circuit view illustrating any one pixel P of FIG. 12.

The circuit view of FIG. 13 is an equivalent circuit view for the pixel P of the display apparatus 1000 that includes an organic light emitting diode (OLED) as a display element 710.

Referring to FIG. 13, the pixel P includes a display element 710 and a pixel driving circuit PDC for driving the display element 710. In detail, the display apparatus 1000 according to one embodiment of the present disclosure may include a pixel driving circuit PDC on the base substrate 110.

The pixel driving circuit PDC of FIG. 13 includes a first thin film transistor TR1 that is a switching transistor and a second thin film transistor TR2 that is a driving transistor. The display apparatus 1000 according to another embodiment of the present disclosure may include at least one of the above-described thin film transistors 100, 200, 300, and 400.

The first thin film transistor TR1 is connected to the gate line GL and the data line DL, and is turned on or off by the scan signal SS supplied through the gate line GL.

The data line DL provides a data voltage Vdata to the pixel driving circuit PDC, and the first thin film transistor TR1 controls applying of the data voltage Vdata.

The driving power line PL provides a driving voltage Vdd to the display element 710, and the first thin film transistor TR1 controls the driving voltage Vdd. The driving voltage Vdd is a pixel driving voltage for driving the organic light emitting diode (OLED) that is the display element 710.

When the first thin film transistor TR1 is turned on by the scan signal SS applied from the gate driver 320 through the gate line GL, the data voltage Vdata supplied through the data line DL is supplied to a gate electrode of the second thin film transistor TR2 connected to the display element 710. The data voltage Vdata is charged in a storage capacitor C1 formed between the gate electrode and a source electrode of the second thin film transistor TR2.

The amount of a current supplied to the organic light emitting diode (OLED), which is the display element 710, through the second thin film transistor TR2 is controlled in accordance with the data voltage Vdata, whereby a gray scale of light output from the display element 710 may be controlled.

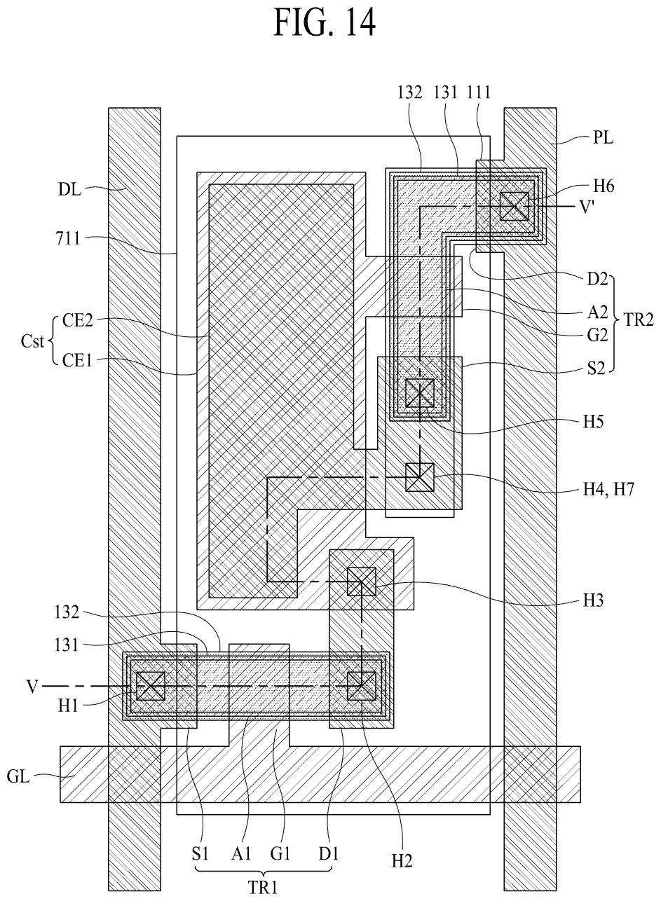

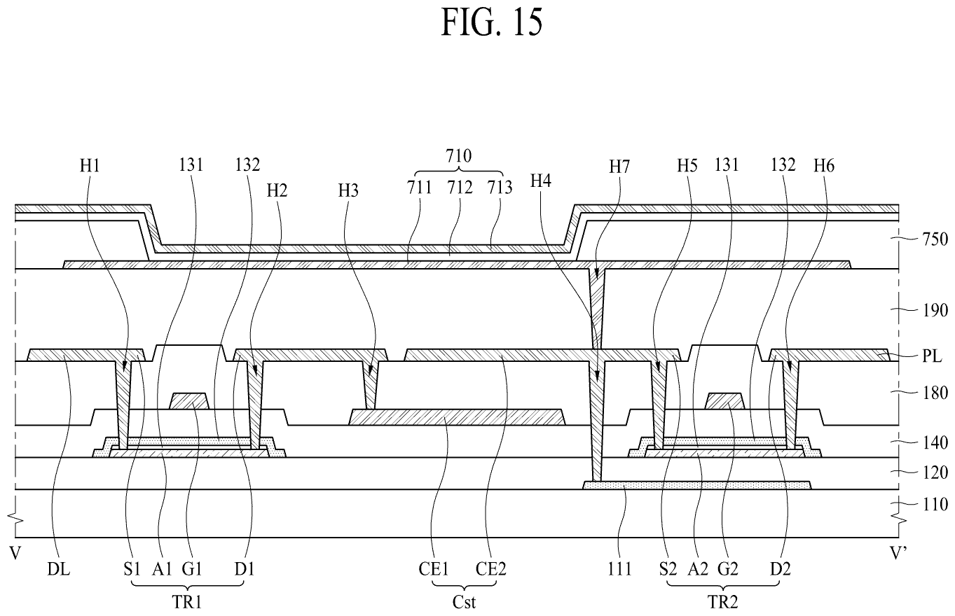

FIG. 14 is a plan view of the pixel of FIG. 13, and FIG. 15 is a cross-sectional view cut along V-V′ of FIG. 13.

Referring to FIGS. 14 and 15, a first thin-film transistor TR1 and a second thin-film transistor TR2 are disposed on a base substrate 110.

The base substrate 110 may be made of glass or plastic. As the base substrate 110, a plastic having flexible properties, such as polyimide (PI), may be used.

A light shielding layer 111 is disposed on the base substrate 110. The light shielding layer 111 may have light-blocking properties. The light shielding layer 111 may protect the active layers A1, A2 by blocking light incident from the outside.

A buffer layer 120 is disposed on the light shielding layer 111. The buffer layer 120 is made of an insulating material and protects the active layers A1, A2 from moisture, oxygen, and the like entering from the outside.

The active layer A1 of the first thin film transistor TR1 and the active layer A2 of the second thin film transistor TR2 are disposed on the buffer layer 120.

The active layers A1, A2 may comprise, for example, an oxide semiconductor material. The active layers A1, A2 may have a multilayer structure of oxide semiconductor material.

A cover insulating film 131 is disposed on the active layers A1, A2, and a first cover layer 132 is disposed on the cover insulating film 131.

The description of the cover insulating film 131 and the first cover layer 132 is redundant and will be omitted.

A gate insulating film 140 is disposed on the active layers A1, A2. The gate insulating film 140 covers the top surface of the active layers A1, A2.

On the gate insulating film 140, the gate electrode G1 of the first thin-film transistor TR1 and the gate electrode G2 of the second thin-film transistor TR2 are disposed.

Although not shown, a gate line GL may be disposed on the gate insulating film 140. The gate electrode G1 of the first thin film transistor TR1 may extend from the gate line GL, or may be part of the gate line GL.

Referring to FIGS. 14 and 15, a first capacitor electrode CE1 of the storage capacitor Cst is formed on the gate insulating film 140. The first capacitor electrode CE1 may be formed by the same process by the same material as the gate electrodes G1, G2.

An interlayer insulating film 180 is disposed on the gate electrodes G1, G2 and the first capacitor electrode CE1.

The data line DL and the drive power line PL are disposed on the interlayer insulating film 180. Further, the source electrode S1 and the drain electrode D1 of the first thin film transistor TR1 are disposed on the interlayer insulating film 180, and the source electrode S2 and the drain electrode D2 of the second thin film transistor TR2 are disposed on the interlayer insulating film 180.

The source electrode S1 of the first thin film transistor TR1 may be formed integrally with the data line DL, and may have a structure extending from the data line DL.

The source electrode S1 of the first thin film transistor TR1 may be in contact with a side of the active layer A1 of the first thin film transistor TR1 through the first contact hole H1.

The drain electrode D1 of the first thin film transistor TR1 is in contact with the other side of the active layer A1 of the first thin film transistor TR1 through the second contact hole H2. Further, the drain electrode D1 of the first thin film transistor TR1 is connected to the first capacitor electrode CE1 through the third contact hole H3. As a result, the first capacitor electrode CE1 can be connected with the first thin film transistor TR1.

The drain electrode D2 of the second thin film transistor TR1 may be formed integrally with the drive power line PL, and may have a structure extending from the drive power line PL.

The drain electrode D2 of the second thin film transistor TR1 may be in contact with a side of the active layer A2 of the second thin film transistor TR2 through the sixth contact hole H6.

The source electrode S2 of the second thin-film transistor TR2 is in contact with another side of the active layer A2 of the second thin-film transistor TR2 through the fifth contact hole H5. Further, the source electrode S2 of the second thin-film transistor TR2 is connected to the light shielding layer 111 through the fourth contact hole H4. A voltage equal to the source electrode S2 of the second thin-film transistor TR2 may be applied to the light shielding layer 111 overlapping the second thin-film transistor TR2.

The source electrode S2 of the second thin film transistor TR2 may extend over the interlayer insulating layer 180 to form the second capacitor electrode CE2 of the storage capacitor Cst.

According to one embodiment of the present disclosure, the first capacitor electrode CE1 and the second capacitor electrode CE2 may be overlapped to form the storage capacitor Cst.

Referring to FIGS. 14 and 15, a planarization layer 190 is disposed on the data line DL, the drive power line PL, the source electrodes S1, S2, the drain electrodes D1, D2, and the second capacitor electrode CE2. The planarization layer 190 planarizes the top of the first thin-film transistor TR1 and the second thin-film transistor TR2, and protects the first thin-film transistor TR1 and the second thin-film transistor TR2. The planarization layer 190 acts as a protective layer.

On the planarization layer 190, the first electrode 711 of the display element 710 is disposed. The first electrode 711 of the display element 710 is in contact with the second capacitor electrode CE2 through the seventh contact hole H7 formed in the planarization layer 190. As a result, the first electrode 711 of the display element 710 can be connected with the source electrode S2 of the second thin film transistor TR2.

A bank layer 750 is disposed on the edge of the first electrode 711. The bank layer 750 defines the light emitting region of the display element 710.

An organic light-emitting layer 712 is disposed on the first electrode 711, and a second electrode 713 is disposed on the organic light-emitting layer 712. Accordingly, the display element 710 is completed. The display element 710 shown in FIG. 15 is an organic light-emitting diode (OLED). Thus, the display apparatus 1000 according to one embodiment of the present disclosure is an organic light-emitting display device.

The pixel drive circuit (PDC) according to another embodiment of the present disclosure may be formed in a variety of structures other than those described above. The pixel drive circuit (PDC) may include, for example, three or more thin film transistors.

According to the present disclosure, the following advantageous effects may be obtained.

A thin film transistor according to one embodiment of the present disclosure can prevent an increase in defects in an active layer due to chemical damage of an etchant by including a cover insulating film and a first cover layer including an oxide semiconductor material.

A thin film transistor according to one embodiment of the present disclosure can reduce the influence of hydrogen by including a cover insulating film and a first cover layer including an oxide semiconductor material.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A thin film transistor comprising:
an active layer;
a cover insulating film on the active layer;
a first cover layer on the cover insulating film; and
a gate electrode spaced apart from the active layer and at least partially overlapping the active layer;
wherein the first cover layer covers a top surface of the cover insulating film and a side surface of the active layer, and
wherein the first cover layer includes an oxide semiconductor material and has a resistivity greater than that of the active layer.

2. The thin film transistor of claim 1, when a longitudinal direction of the active layer is referred to as a first direction and a direction perpendicular to the first direction is referred to as a second direction,
wherein the first cover layer can cover the side surface of the active layer based on the first direction and the second direction.

3. The thin film transistor of claim 1, wherein the first cover layer is in contact with the top surface of the cover insulating film and the side surface of the active layer.

4. The thin film transistor of claim 1, wherein the cover insulating film is patterned, and
the first cover layer is in contact with the side surface of the cover insulating film.

5. The thin film transistor of claim 1, wherein an entire area of the cover insulating film is on the active layer.

6. The thin film transistor of claim 1, wherein the first cover layer includes an oxide semiconductor material,
wherein the first cover layer includes at least one of an IGZO (InGaZnO)-based oxide semiconductor material, an IGO (InGaO)-based oxide semiconductor material, an IGZTO (InGaZnSnO)-based oxide semiconductor material, a GZTO (GaZnSnO)-based oxide semiconductor material, a GZO (GaZnO)-based oxide semiconductor material, and a GO (GaO)-based oxide semiconductor material, and
wherein the first cover layer has a higher concentration of oxygen atom than the active layer.

7. The thin film transistor of claim 1, wherein the cover insulating film includes any one of silicon oxide (SiOx) and aluminum oxide (Al2O3).

8. The thin film transistor of claim 1, wherein the first cover layer is thinner than the active layer, and the first cover layer has a thickness of 1 to 3 nm.

9. The thin film transistor of claim 1, wherein the cover insulating film has a thickness of 2 to 5 nm.

10. The thin film transistor of claim 1, wherein the first cover layer has a resistivity of 100 to 1,000 Ω·cm.

11. The thin film transistor of claim 1, further includes a gate insulating film between the first cover layer and the gate electrode, and
wherein the resistivity of the first cover layer is greater than the resistivity of the active layer and lower than the resistivity of the gate insulating film.

12. The thin film transistor of claim 1, further includes a source electrode and a drain electrode spaced apart from each other and respectively connected to the active layer, and
wherein the source electrode and the drain electrode contact the active layer through a contact hole penetrating the cover insulating film and the first cover layer.

13. The thin film transistor of claim 1, when a longitudinal direction of the active layer is referred to as a first direction and a direction perpendicular to the first direction is referred to as a second direction,
wherein the first cover layer includes:
a first side cover layer covering one side of the active layer with respect to the second direction; and
a second side cover layer covering the other side of the active layer with respect to the second direction,
wherein the first side cover layer and the second side cover layer are spaced apart from each other.

14. The thin film transistor of claim 1, further includes a second cover layer in contact with the bottom surface of the active layer,
wherein the second cover layer includes an oxide semiconductor material and has a resistivity greater than that of the active layer.

15. The thin film transistor of claim 14, wherein the second cover layer includes an oxide semiconductor material,
wherein the second cover layer includes at least one of an IGZO (InGaZnO)-based oxide semiconductor material, an IGO (InGaO)-based oxide semiconductor material, an IGZTO (InGaZnSnO)-based oxide semiconductor material, a GZTO (GaZnSnO)-based oxide semiconductor material, a GZO (GaZnO)-based oxide semiconductor material, and a GO (GaO)-based oxide semiconductor material, and
wherein the second cover layer has a higher concentration of oxygen atom than the active layer.

16. The thin film transistor of claim 14, wherein the second cover layer is patterned, and the second cover layer contact the first cover layer.

17. The thin film transistor of claim 14, wherein the second cover layer has a thinner thickness than the active layer, and
wherein the second cover layer has a thickness of 1 to 3 nm.

18. A manufacturing method of a thin film transistor comprising:
forming an active layer;
forming a cover insulating film on the active layer;
forming a first cover layer on the cover insulating film; and
forming a gate electrode on the first cover layer, and
forming the active layer and the cover insulating film includes:
sequentially depositing the oxide semiconductor material layer and the cover insulating material layer; and
concurrently wet-etching the oxide semiconductor material layer and the cover insulating material layer,
wherein the first cover layer covers the top surface of the cover insulating film and the side surface of the active layer, and
wherein the first cover layer includes an oxide semiconductor material and has a resistivity greater than that of the active layer.

19. The manufacturing method of a thin film transistor of claim 18, wherein the first cover layer includes an oxide semiconductor material,
wherein the first cover layer includes at least one of an IGZO (InGaZnO)-based oxide semiconductor material, an IGO (InGaO)-based oxide semiconductor material, an IGZTO (InGaZnSnO)-based oxide semiconductor material, a GZTO (GaZnSnO)-based oxide semiconductor material, a GZO (GaZnO)-based oxide semiconductor material, and a GO (GaO)-based oxide semiconductor material, and
wherein the first cover layer has a higher concentration of oxygen atom than the active layer.

20. A display apparatus comprising:
a light emitting diode;
a thin film transistor coupled to the light emitting diode, the thin film transistor including:
an active layer;
a cover insulating film on the active layer,
a first cover layer on the cover insulating film; and
a gate electrode spaced apart from the active layer and at least partially overlapping the active layer,
wherein the first cover layer covers a top surface of the cover insulating film and a side surface of the active layer, and
wherein the first cover layer includes an oxide semiconductor material and has a resistivity greater than that of the active layer.
